(19) United States
(12) Patent Application Publication
(10) Pub. No.: US 2025/0159784 A1
(43) Pub. Date: May 15, 2025

(54) WIDE AREA INSTALLATION ENTERTAINMENT APPARATUS AND ENTERTAINMENT SYSTEM USING THE ENTERTAINMENT APPARATUS

(71) Applicant: ELM INC., Minamisatsuma-shi, Kagoshima (JP)

(72) Inventor: Takakazu MIYAHARA, Minamisatsuma-shi (JP)

(73) Assignee: ELM INC., Minamisatsuma-shi, Kagoshima (JP)

(21) Appl. No.: 18/728,703

(22) PCT Filed: Dec. 13, 2022
(86) PCT No.: PCT/JP2022/045847

§ 371 Date: Jul. 12, 2024

(30) Foreign Application Priority Data
Jan. 12, 2022 (JP) 2022-002977

(51) Int. Cl. H05B 47/19; G01R 31/382; H04R 3/00

(52) U.S. Cl. CPC H05B 47/19; G01R 31/382; H04R 3/00

(57) ABSTRACT

An entertainment system (30) includes: a plurality of entertainment apparatuses (10) each including an entertainment presentation unit (12) having one or both of a light emitting unit capable of emitting a plurality of types of light and a sound producing unit capable of producing sound, a group number storage unit (14) configured to store a group number, a wireless communication unit (13) configured to wirelessly receive control information for controlling an operation of the entertainment presentation unit assigned to the group number, and a control unit (15) configured to control one or both of the light emitting unit and the sound producing unit of the entertainment presentation unit based on the control information received by the wireless communication unit and the group number stored in the group number storage unit; an information generation device (31) configured to generate the control information for the group number assigned to each of the plurality of entertainment apparatuses; and a control information transmission wireless communication device (32) configured to wirelessly transmit the control information for each group number generated by the information generation device to all of the plurality of entertainment apparatuses.

### TECHNICAL FIELD

The present invention relates to an entertainment apparatus installed in a wide area, and an entertainment system using the entertainment apparatus. Here, the entertainment apparatus includes, for example, a lamp capable of emitting light of a plurality of colors, details of which will be described later.

### BACKGROUND ART

In recent years, as LED elements have become more sophisticated, lamps that can emit multiple colors and have wired or wireless (RF) communication functions have been manufactured, and vivid and highly varied illumination events have been held in various regions. Large-scale and quiet illumination events, such as one in Shiroyone Senmaida Rice Terraces of Noto, using a large number of lamps changing in color by a timer are held in a wide range of outdoors. Further interactive illumination events are held in which participants hold a cane (stick) or a lantern incorporating a multicolor lamp by an LED having a communication function, and the color changes depending on a zone or music (Patent Literatures 1 to 5 and Non Patent Literatures 1 and 2).

### CITATION LIST

### Patent Literature

Patent Literature 1: JP 2020-115455 A
Patent Literature 2: JP 2021-093384 A
Patent Literature 3: JP 2005-251443 A
Patent Literature 4: JP 2010-507218 A
Patent Literature 5: WO 2016/114331 A

### Non Patent Literature

Non Patent Literature 1: “Color kinetics FLEX”, [online], Color Kinetics Japan Incorporated, [searched on Nov. 18, 2022], Internet <URL: https://www.colorkinetics.co.jp/products/948>
Non Patent Literature 2: “CSR topic WAJIMA NARRATIVE with ISHIKAWA SANKEN”, [online], Sanken Electric Co., Ltd., [searched on Nov. 18, 2022], Internet <URL: https://www.sanken-ele.co.jp/corp/csr/topics/wajima.htm>

### SUMMARY OF INVENTION

### Technical Problem

However, the illumination apparatuses described in Patent Literatures 1 and 2 are illumination apparatuses or illumination systems for controlling general illumination although they can freely change the color and brightness, and a large amount of money is required to install many thousands or tens of thousands of lamps in a wide area. Therefore, they are not easy to use in terms of cost and power consumption.

The apparatus described in Patent Literature 3 is easy to install since the communication system is wireless and battery driven, but it is necessary that each light emitting device should have a unique identification number, and color or brightness is instructed for each identification number. Therefore, in order to control a large number of light emitting devices, 10,000 for example, high-speed communication is required, and the power consumption of each light emitting device rises to increase the cost, making them less marketable.

The apparatus described in Patent Literature 4 is not suitable for use in large quantities for the same reason as that described in Patent Literature 3, though the communication method can be selected from wired/wireless, and the power source can be selected in a wide range from AC to solar.

Unlike the above case, the apparatus described in Patent Literature 5 introduces the concept of groups, but the groups are used to set the same color and brightness values during control, and since each lamp has its own unique number, the amount of control information (communication volume) as a whole remains the same.

The lamp described in Non Patent Literature 1 is a wired lamp which has been often seen in recent years, and can perform full color control of individual light emission at high speed, so that large-scale illumination with movement is possible. However, in terms of cost and installation work, it is difficult to use the lamp for an application other than highly profitable applications such as commercial facilities.

The lamps described in Non-Patent Document 2 are inexpensive and can be installed in large numbers and over wide areas because they are simply plugged into the ground or hung, but they are controlled by an internal timer, making complex changes and fast-flowing, linked control impossible.

An object of the present invention is to compensate for the disadvantages of the conventional lamp for general illumination controlled by the above-described existing wireless communication and the conventional lamp which can only perform simple control with slow movement by a timer, and to provide an entertainment such as an inexpensive and harmonized fast-moving illumination using a large number of entertainment apparatuses such as lamps.

### Solution to Problem

An entertainment apparatus according to the present invention made to solve the above problems includes:
a) an entertainment presentation unit having one or both of a light emitting unit capable of emitting a plurality of types of light and a sound producing unit capable of producing sound;
b) a group number storage unit configured to store a group number;
c) a wireless communication unit configured to wirelessly receive control information for controlling an operation of the entertainment presentation unit assigned to the group number; and
d) a control unit configured to control one or both of the light emitting unit and the sound producing unit of the entertainment presentation unit based on the control information received by the wireless communication unit and the group number stored in the group number storage unit.

An entertainment system according to the present invention includes:
a plurality of entertainment apparatuses each including an entertainment presentation unit having one or both of a light emitting unit capable of emitting a plurality of types of light and a sound producing unit capable of producing sound, a group number storage unit configured to store a group number; a wireless communication unit configured to wirelessly receive control information for controlling an operation of the entertainment presentation unit assigned to the group number, and a control unit configured to control one or both of the light emitting unit and the sound producing unit of the entertainment presentation unit based on the control information received by the wireless communication unit and the group number stored in the group number storage unit;
an information generation device configured to generate the control information for the group number assigned to each of the plurality of entertainment apparatuses; and
a control information transmission wireless communication device configured to wirelessly transmit the control information for each group number generated by the information generation device to all of the plurality of entertainment apparatuses.

The term “plurality of types of light” refers to a plurality of types of light having different colors and/or intensities. Therefore, the control of the light emission performed by the control unit refers to the control of the colors and/or intensities of these types of light. In addition, the control of the sound production performed by the control unit refers to the control of the entire waveform including the frequency (including superposition of a plurality of frequencies) and/or the intensity of the sound.

The entertainment apparatus according to the present invention is an apparatus including one or both of a light emitting unit and a sound producing unit. The entertainment apparatus is embodied by a lamp including a light emitting unit, a speaker including a sound producing unit, a speaker-equipped lamp including both the light emitting unit and the sound producing unit, and the like.

In the entertainment apparatus and the entertainment system according to the present invention, a group number is assigned to each of the plurality (hereinafter referred to as “total number”) of entertainment apparatuses. That is, a total number (defined as N) of entertainment apparatuses are divided into a plurality (M, where M<N) of groups, and the same group number is assigned to entertainment apparatuses belonging to the same group. Here, the number of entertainment apparatuses belonging to each group may be different in each group.

The group number may be stored in advance in the group number storage unit. Alternatively, the group number may be generated by the information generation device, and then transmitted, by the wireless communication device, to all the entertainment apparatuses belonging to (or to be set to) the same group, so that each of the one or plurality of entertainment apparatuses which have received the radio (disposed at a receivable position) stores the group number in the group number storage unit. In the latter case, the wireless communication device transmitting the group number may also be used as the control information transmission wireless communication device, or a group number setting wireless communication device different from the control information transmission wireless communication device may be used. In addition, in the latter case, the group number is transmitted separately to two or more groups.

The total number of entertainment apparatuses having the group numbers stored in the group number storage unit are disposed at positions corresponding to the respective group numbers. Then, when the control information for each group number is transmitted by wireless communication using the control information transmission wireless communication device to the total number of entertainment apparatuses, in each entertainment apparatus, the wireless communication unit receives the control information, and the control unit controls the entertainment presentation unit so as to execute an operation specified by the control information of the group number stored in the group number storage unit. That is, the control unit controls the light emitting unit to emit light in the color and/or brightness designated by the control information in a case where the entertainment presentation unit includes the light emitting unit, and controls the sound producing unit to produce sound with the waveform designated by the control information in a case where the entertainment presentation unit includes the sound producing unit. In a case where the entertainment presentation unit includes both the light emitting unit and the sound producing unit, both of the above two controls are performed. Accordingly, entertainment apparatuses with the same group number emit light in the same color and/or brightness, and/or produce sound with the same waveform. Then, with the transmission of different control information for each group number by wireless communication using the control information transmission wireless communication device, different groups emit light in different colors and/or brightness, and/or produce sound with different waveforms.

According to the entertainment apparatus and the entertainment system according to the present invention, the total number (N) of lamps are divided into a plurality (M) of groups, the entertainment apparatuses belonging to the same group are caused to emit light in the same color and brightness and/or produce sound with the same waveform, and the entertainment apparatuses in different groups are caused to emit light in different colors and/or brightness and/or produce sounds with different waveforms. This configuration makes it possible to construct an entertainment system using a large number of entertainment apparatuses at low cost and with ease as compared with a case of controlling individual entertainment apparatuses. In addition, since the operations of a large number of entertainment apparatuses are controlled by wireless communication, it is possible to realize harmonized fast-moving illumination and realistic sound by variously changing control information transmitted by wireless communication in time series.

The group number storage unit of the entertainment apparatus may store two or more (a plurality of) group numbers. In this case, each of the two or more group numbers is stored in a different page (also referred to as bank) in the group number storage unit. The plurality of pages each have a page number (or bank number), and a group number is stored in a page having a page number in the group number storage unit. In the operation of the illumination system, firstly the control information transmission wireless communication device transmits a page number (bank number), and then each of the entertainment apparatuses which has received the page number refers to a page having the page number. Then, the control information transmission wireless communication device transmits a group number and control information assigned to the group number, and the entertainment apparatus storing, in the referred page, the group number matched with the received group number emits light in the color and/or brightness, and/or produces sound in a waveform according to the control information.

By setting the group number for each page in this manner, the light emission pattern and the sound production pattern of the entertainment apparatus can be changed by changing the page number transmitted by the control information transmission wireless communication device, and thus more varied illumination and sound can be realized.

In a case where the group number setting wireless communication device is used to set the group number for each page, the wireless communication unit included in the entertainment apparatus may be further configured to wirelessly receive the page number (together with the group number), and the group number setting wireless communication device may be configured to transmit the page number and the group number.

The entertainment apparatus according to the present invention can employ a configuration in which
the entertainment presentation unit includes both the light emitting unit and the sound producing unit, and the operation of the entertainment presentation unit assigned to the group number is an operation of one of the light emitting unit and the sound producing unit,
the group number storage unit is further configured to store a second group number,
the wireless communication unit is further configured to wirelessly receive second control information for controlling the operation of the other one of the light emitting unit and the sound producing unit assigned to the second group number, and
the control unit is configured to control the operation of the one based on the control information and the group number stored in the group number storage unit, and control the operation of the other one based on the second control information and the second group number stored in the group number storage unit.

In this case, the entertainment system can employ a configuration in which
the information generation device is further configured to generate the second control information for each of the second group numbers, and
the control information transmission wireless communication device is further configured to wirelessly transmit the second control information to all of the plurality of entertainment apparatuses.

As described above, in the entertainment apparatus including both the light emitting unit and the sound producing unit as the entertainment presentation unit, the operation of one of the light emitting unit and the sound producing unit is assigned to the group number, and the operation of the other one of the light emitting unit and the sound producing unit is assigned to the second group number, whereby the light emitting unit and the sound producing unit are controlled as different groups. As a result, the light emitting unit and the sound producing unit can be controlled independently of each other, so that more complicated expression can be realized.

Similarly to the group number, the second group number may be stored in advance in the group number storage unit. Otherwise, the second group numbers may be generated by the information generation device. In that case, the second group numbers are transmitted to the entertainment apparatuses by the wireless communication device (control information transmission wireless communication device, or group number setting wireless communication device different from control information transmission wireless communication device), and stored in the group number storage unit of each of the entertainment apparatuses.

It is preferable that the entertainment apparatus according to the present invention further includes a power supply unit configured to supply power to the entertainment presentation unit. The power supply unit may be a primary battery or a secondary battery. In this case, it is not necessary to connect wiring for supplying power to each individual entertainment apparatus, which can reduce labor required for installation.

It is preferable that the power supply unit includes a solar power generation panel and a secondary battery. As a result, it is not necessary to replace the primary battery or to charge a separate secondary battery, which can reduce labor.

The entertainment apparatus according to the present invention including the power supply unit may further include
a remaining amount measurement unit configured to measure a remaining amount of the primary battery or the secondary battery; and
an output control unit configured to perform control to reduce output of the entertainment presentation unit when a remaining amount measured by the remaining amount measurement unit is equal to or less than a predetermined value.

According to the configuration including the remaining amount measurement unit and the output control unit, by reducing the output of the entertainment presentation unit when the remaining amount of the primary battery or the secondary battery of the power supply unit is equal to or less than a predetermined value, it is possible to extend the time before the entertainment apparatus stops due to battery exhaustion. By extending the time to battery exhaustion, the time for replacing the primary battery or charging the secondary battery can be secured, and it is possible to prevent the entertainment apparatus from stopping.

### Advantageous Effects of Invention

According to the present invention, it is possible to provide an entertainment with harmonized fast-moving illumination and realistic sound using a large number of entertainment apparatuses at low cost.

### BRIEF DESCRIPTION OF DRAWINGS

FIG. 1 is a diagram illustrating a first embodiment of an illumination lamp which is an entertainment apparatus according to the present invention.

FIG. 2 is a diagram illustrating a first embodiment of an illumination system which is an entertainment system according to the present invention.

FIG. 3 is a diagram illustrating a state when the lamp of the first embodiment is used for wide area installation illumination.

FIGS. 4A, 4B, 4C, and 4D are diagrams illustrating states in which group numbers are assigned to lamps of the first embodiment.

FIGS. 5A and 5B are diagrams illustrating examples of communication contents when group numbers are set to the lamps of the first embodiment.

FIG. 6 is a diagram illustrating an example of causing the lamps to emit light to which the group numbers illustrated in FIGS. 5A and 5B are set.

FIG. 7 is a diagram illustrating an example of communication contents of control information for causing the lamps to emit light to which the group numbers illustrated in FIGS. 5A and 5B are set.

FIG. 8 is a diagram illustrating how illumination is temporally changed while causing the lamps of the first embodiment to emit light.

FIG. 9 is a diagram illustrating a lamp according to a second embodiment.

FIGS. 10A and 10B are diagrams illustrating examples of communication contents when group numbers are set to the lamps of the second embodiment.

FIG. 11 is a diagram illustrating an example of causing the lamps to emit light to which the group numbers illustrated in FIGS. 10A and 10B are set.

FIG. 12 is a diagram illustrating an example of communication contents when a page number is designated to the lamps to which the group numbers illustrated in FIGS. 10A and 10B are set.

FIG. 13A is a diagram illustrating, when a page number “1” is set to the lamps of the second embodiment, how illumination is temporally changed while causing the lamps to emit light.

FIG. 13B is a diagram illustrating, when a page number “2” is set to the lamps of the second embodiment, how illumination is temporally changed while causing the lamps to emit light.

FIG. 14 is a diagram illustrating a lamp according to a third embodiment.

FIG. 15 is a diagram illustrating an illumination system according to the third embodiment.

FIG. 16 is a diagram illustrating a state when the lamp of the third embodiment is used for wide area installation illumination.

FIG. 17 is a diagram illustrating a speaker-equipped lamp according to a fourth embodiment.

FIG. 18 is a diagram illustrating an illumination system which is an entertainment system according to the fourth embodiment.

FIG. 19 is a diagram illustrating an example of communication contents of control information for causing speaker-equipped lamps to which group numbers are set to emit light and produce sound in the fourth embodiment.

FIG. 20 is a diagram illustrating a speaker-equipped lamp according to a fifth embodiment.

FIG. 21 is a diagram illustrating an example of assigning first group numbers and second group numbers in the fifth embodiment.

FIG. 22 is a diagram illustrating an example of communication contents of control information according to the fifth embodiment.

FIG. 23 is a diagram illustrating an example of light emission for the first group and sound production for the second group of the speaker-equipped lamp in the fifth embodiment.

FIG. 24 is a diagram illustrating a lamp of a modification.

### DESCRIPTION OF EMBODIMENTS

Embodiments of the present invention will be described below with reference to the drawings. Hereinafter, firstly illumination lamps (hereinafter abbreviated as “lamps”) which are entertainment apparatuses including only a light emitting unit (not including a sound producing unit) and illumination systems which are entertainment systems using the lamps according to first to third embodiments will be described. Next, speaker-equipped lamps which are entertainment apparatuses having a light emitting unit and a sound producing unit (speaker) and illumination systems using the speaker-equipped lamps according to fourth to sixth embodiments will be described. Finally, a modification including an entertainment apparatus including only a sound producing unit (not including a light emitting unit) and an entertainment system using the same will be described.

### (1) First Embodiment

### (1-1) Configuration of Lamp and Illumination System of First Embodiment

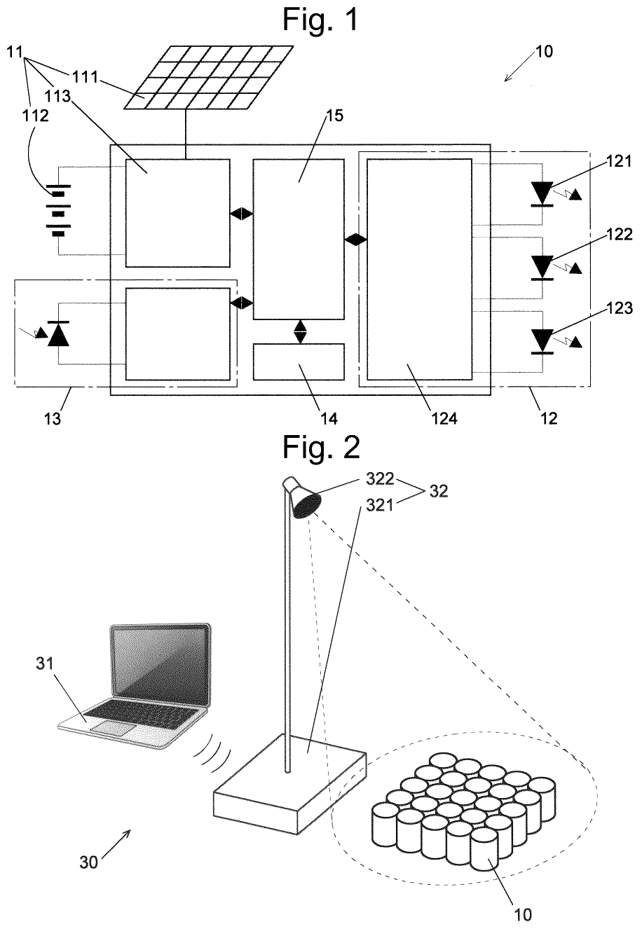

FIG. 1 is an embodiment related to a lamp. This lamp 10 includes a power supply unit 11, a light emitting unit 12, an infrared communication reception circuit (corresponding to the wireless communication unit) 13, a nonvolatile memory (group number storage unit) 14, and a CPU circuit 15. The power supply unit 11 includes a solar power generation panel 111, a secondary battery 112, and a power supply circuit 113 which controls the solar power generation panel 111 and the secondary battery 112. The light emitting unit 12 includes three LED elements 121 to 123 which emit different colors, that is, a red LED element 121 which emits red light, a green LED element 122 which emits green light, and a blue LED element 123 which emits blue light, and an LED lighting circuit 124 which controls these LED elements 121 to 123. The infrared communication reception circuit 13 receives infrared rays transmitted from an infrared communication device 32 described later. The nonvolatile memory 14 is a rewritable memory that maintains stored contents even when power supply is interrupted. The nonvolatile memory 14 stores a group number received by the infrared communication reception circuit 13 as described later.

The CPU circuit 15 is a control unit that collectively controls the power supply unit 11, the light emitting unit 12, the infrared communication reception circuit 13, and the nonvolatile memory 14. Note that when, for example, control units included in an existing power supply device, light emitting device, infrared communication device, or nonvolatile memory is used, (a plurality of) control units which individually control the units may be used instead of one CPU circuit 15 that performs collective control as described above.

FIG. 2 illustrates an illumination system 30 according to the first embodiment. The illumination system 30 includes a plurality of lamps 10, a personal computer 31 which is an information generation device generating a group number assigned to each of the plurality of lamps 10 and control information assigned to the lamp 10 to which the group number is assigned, and the infrared communication device 32 which is wirelessly connected to the personal computer 31 and sends a signal of the group number and the control information to the lamps 10 via infrared communication. The infrared communication device 32 includes an infrared communication interface 321 and an infrared communication signal transmission unit 322, and functions as the group number setting wireless communication device and the control information transmission wireless communication device. Note that the personal computer 31 and the infrared communication device 32 may be connected by wire, but it is preferable to connect them wirelessly as described above because installation work becomes easy. In addition, two sets of the personal computer 31 and the infrared communication device 32 may be prepared, and the one set may be used as the group number setting wireless communication device and the other set may be used as the control information transmission wireless communication device. By using the personal computer 31 and the infrared communication device 32 together, it is possible to collectively program the plurality of lamps 10 for which the same group number is set as described later.

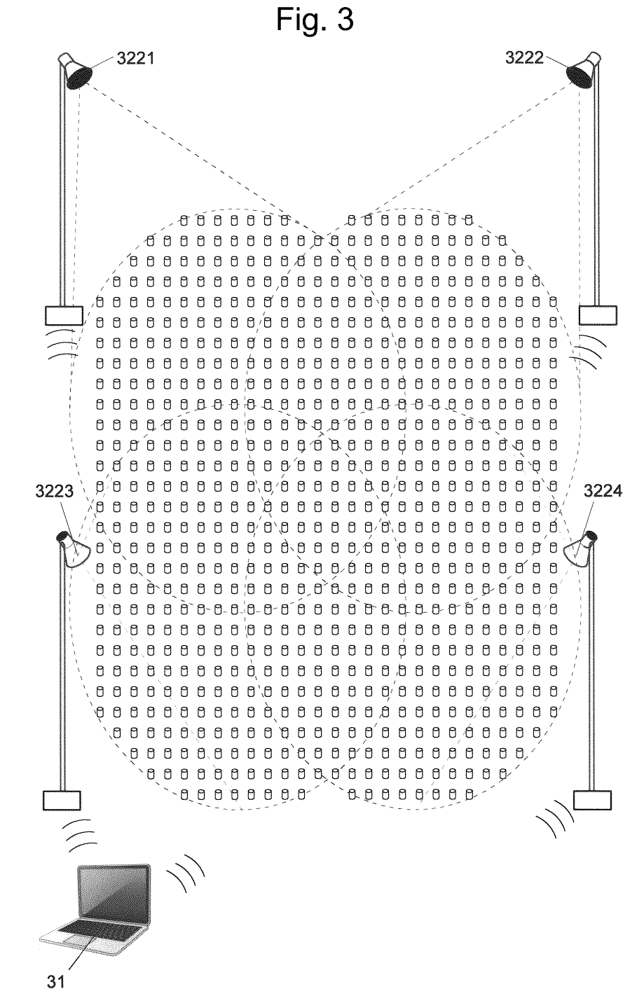

FIG. 3 illustrates an example of a case where a control signal is distributed to all of a large number of lamps installed in a wide area via infrared communication, and one personal computer 31 and four infrared communication signal transmission units 3221 to 3224 wirelessly connected to the personal computer 31 are disposed. In a case where all the lamps are in a visible range, it is also possible to perform control with one high-output infrared transmitter. Also in this example, the personal computer 31 and the infrared communication signal transmission units 3221 to 3224 may be connected by wire, but it is preferable to connect them wirelessly because installation work becomes easy.

### (1-2) Operation of Lamp and Illumination System of First Embodiment

Hereinafter, operation of the lamp and the illumination system according to the first embodiment will be described. In the first embodiment, after the operation of setting the group number to each lamp is performed, lighting of each lamp is controlled to generate illumination with change.

### (1-2-1) Operation of Setting Group Number

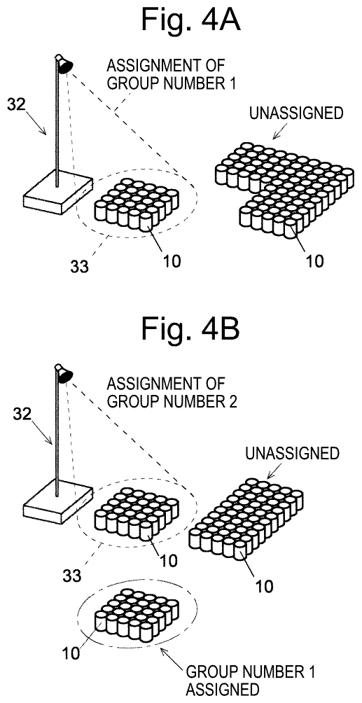

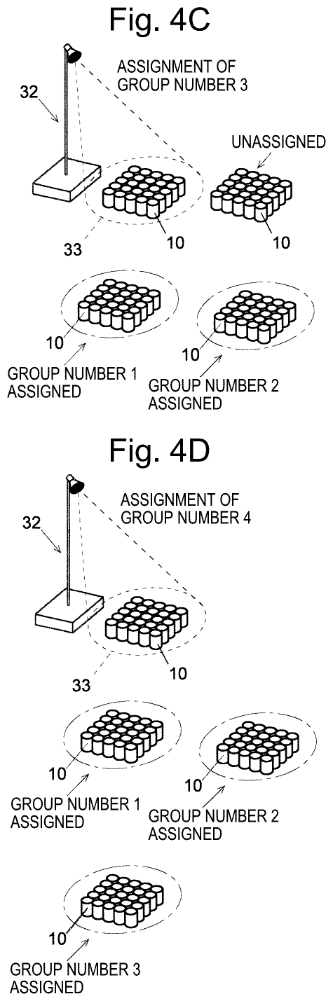

FIGS. 4A to 4D schematically illustrate an operation in a case where any group number of 01 to 04 is set to all (total number) of the plurality of lamps 10 (note that in FIGS. 4A to 4D, FIG. 6 described later, and the like, “0” of the first digit is omitted from the top). Note that the number of group numbers to be set is not limited to four in this example, as long as the number is two or more. In addition, in FIGS. 4A to 4D, the group numbers 01 to 04 are illustrated to be set to the same number of lamps 10, but the setting may be performed for different numbers of lamps for each group number.

Firstly, as illustrated in FIG. 4A, among the total number of lamps 10, the lamps 10 for which the group number 01 is set are disposed in an area 33 capable of receiving an infrared signal transmitted by the infrared communication device 32. The other lamps may be disposed outside the area 33 as illustrated in FIG. 4A, and in addition to or instead of this disposition, may be covered with a cover that blocks infrared rays.

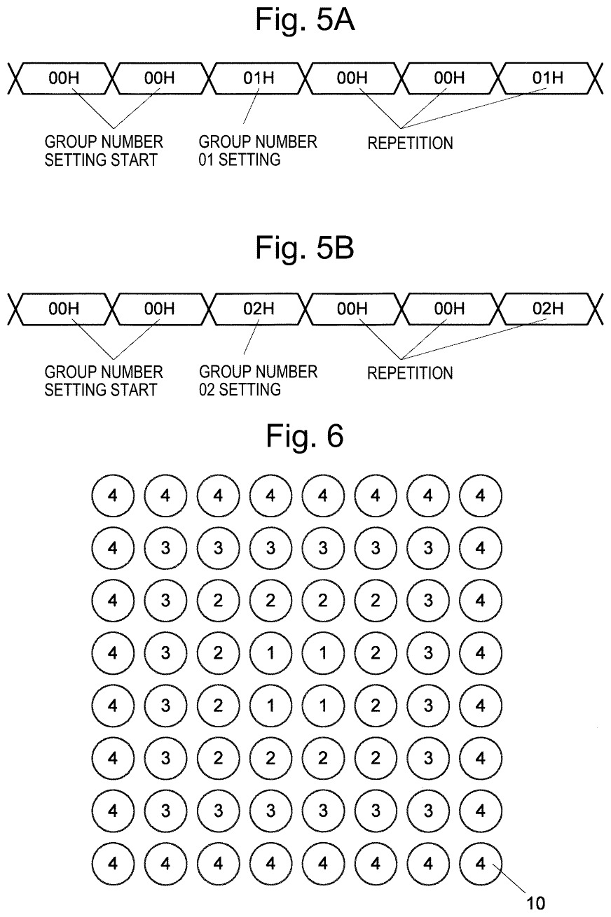

Then, as illustrated in FIG. 5A, the following group number setting signal is generated by the personal computer 31, and the group number setting signal is transmitted from the infrared communication device 32 to the lamps in the area 33. In this example, the infrared communication device 32 transmits “00H”, which is a group number setting start signal, to the lamps 10 twice and the lamps 10 enter the group number setting mode, and then the infrared communication device 32 transmits a signal “01H” representing a group number. The first two digits “01” of this signal represent the group number. The group number setting signal including 00H, 00H, and 01H described above is repeatedly transmitted a plurality of times. As the lamps 10 receive the same command a plurality of times in this manner, it is possible to prevent malfunction. The lamps in the area 33 receive this signal and write their own group number “01” into the nonvolatile memory 14.

Next, the lamps 10 that have written the group number 1 are taken out from the area 33, and then, among the lamps 10 for which the group number has not been set yet, the lamps for which the group number 02 is set are disposed in the area 33 (FIG. 4B). Then, similarly to the above, the infrared communication device 32 transmits the group number setting signal (FIG. 5B) for setting the group number “02” to the lamps in the area 33, and the lamps in the area 33 having received the signal write the group number “02” into the nonvolatile memory 14.

The similar operation is performed for the group numbers 03 and 04 (FIGS. 4C and 4D) and thus any one of the group numbers 01 to 04 is set for all the lamps 10.

In the group number setting operation described above, the lamps that have normally completed the instructed work (writing of the group number) may, for example, emit light of the green LED for a short time and the lamps that have abnormality may emit light of the red LED for a long time. These lighting operations may be performed while the lamps 10 repeatedly receive the group number setting signal a plurality of times as described above. These lighting operations make it possible to easily determine whether or not the setting of the group number is normally completed.

The total number of lamps 10 having the group numbers stored in the nonvolatile memory 14 are installed at a site where illumination is to be performed. FIG. 6 illustrates an installation example of these lamps 10 on site. In practice, more lamps are used, but for ease of illustration and understanding, an example of 8×8=64 lamps will be described. In FIG. 6, 64 circles each represent one lamp 10, and the number written at the center of each circle represents the group number (as described above, the first digit from the top of the group number is omitted). In this example, 4 lamps 10 of the group number 01 are disposed at the center, 12 lamps 10 of the group number 02 are disposed on the outer side, 20 lamps 10 of the group number 03 are disposed on the further outer side, and 28 lamps 10 of the group number 04 are disposed on the outermost circumference.

### (1-2-2) Control of Lighting of Each Lamp

In order to use (turn on) the lamps, the following control signal is generated by the personal computer 31, and then the control signal is transmitted from the infrared communication device 32 simultaneously to all the lamps 10. First, the infrared communication device 32 transmits the control start code “FFH” and then transmits a group number designation code “XnnH” (where “nn” is a group number) for designating a group number. Next, the infrared communication device 32 transmits color-specific intensity designation codes indicating an intensity of red “RmmH”, an intensity of green “GmmH”, and an intensity of blue “BmmH”. Here, “mm” is a numerical value indicated by 2 digits (256 levels) hexadecimally, and as this numerical value increases, the LED elements 121 to 123 corresponding to the respective colors of the lamps 10 of the group designated by the group number designation code emit brighter light (with higher intensity). Note that, here, the numerical values of red, green, and blue are all denoted by the same “mm”, but actually, they are set for each color.

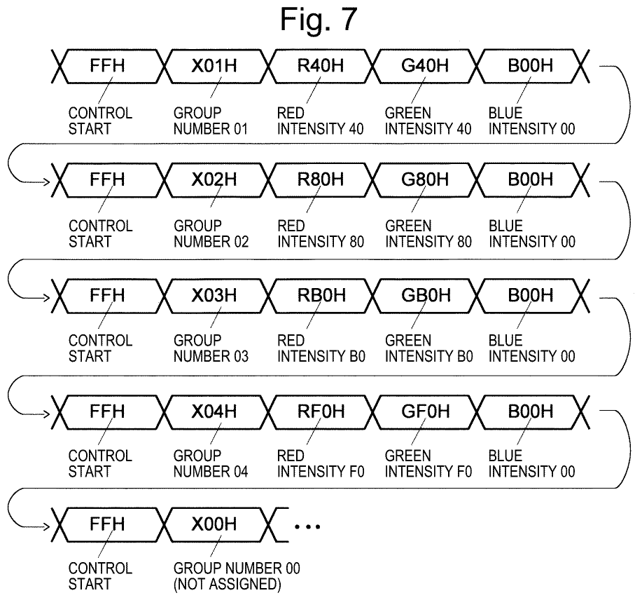

FIG. 7 illustrates an example of the control signal. In this example, after the control start signal “FFH” is transmitted, the group number designation signal “X01H” and the color-specific intensity designation signals “R40H”, “G40H”, and “B00H” are transmitted. These control signals means that the innermost 4 lamps 10 to which the group number 01 is assigned are caused to emit light such that the red has an intensity of the 64th level (an intensity obtained by counting decimally from the weaker side, assuming that the intensity of 0 is “0th level”, and the same applies hereinafter), the green has an intensity of the 64th level, and the blue has an intensity of 0. With red and green being lit at an intensity ratio of 1:1 in this manner, the lighting color becomes yellow. In the present embodiment, as will be described below, the lamps having the group numbers 02 to 04 also emit light with the red and green intensity ratio of 1:1 (the intensity value is different for each group) and the lighting color becomes yellow.

Subsequently, the control start signal “FFH” is transmitted and then the group number designation signal “X02H” and the color-specific intensity designation signals “R80H”, “G80H”, and “B00H” are transmitted. These control signals mean that the 12 lamps to which the group number 02 is assigned are caused to emit light such that the red has an intensity of the 128th level, the green has an intensity of the 128th level, and the blue has an intensity of 0. Further, the control start signal “FFH” is transmitted and then the group number designation signal “X03H” and the color-specific intensity designation signals “RB0H”, “GB0H”, and “B00H” are transmitted, and after the control start signal “FFH” is further transmitted, the group number designation signal “X04H” and the color-specific intensity designation signals “RF0H”, “GF0H”, and “B00H” are transmitted. These control signals mean that the 20 lamps 10 to which the group number 03 is assigned are caused to emit light such that the red has an intensity of the 176th level, the green has an intensity of the 176th level, and the blue has an intensity of 0, and the lamps 10 of the group 04 at the outermost periphery are caused to emit light such that the red has an intensity of the 240th level, the green has an intensity of the 240th level, and the blue has an intensity of 0.

As described above, the lamps 10 in the four groups are set to any one of the four lighting states in which the lighting color is yellow and the intensities are different from each other. Hereinafter, when the color-specific intensity designation signals are “R40H”, “G40H”, and “B00H”, the lighting state is referred to as “darkest yellow”, when the signals are “R80H”, “G80H”, and “B00H”, the lighting state is referred to as “third brightest yellow”, when the signals are “RB0H”, “GB0H”, and “B00H”, the lighting state is referred to as “second brightest yellow”, and when the signals are “RF0H”, “GF0H”, and “B00H”, the lighting state is referred to as “brightest yellow”.

Next, after the time (generally one to several seconds) designated by a program has elapsed, the personal computer 31 generates a total of four types of control signals for lighting X01H in the brightest yellow, X02H in the darkest yellow, X03H in the third brightest yellow, and X04H in the second brightest yellow by the same method as described above, and then the infrared communication device 32 sequentially transmits the control signals to all the lamps 10. Further, after the time designated by the program has elapsed, the personal computer 31 generates a total of four types of control signals for lighting X01H in the second brightest yellow, X02H in the brightest yellow, X03H in the darkest yellow, and X04H in the third brightest yellow, and similarly the infrared communication device 32 sequentially transmits the control signals to all the lamps 10. Finally, after the time designated by the program has elapsed, the personal computer 31 generates a total of four types of control signals for lighting X01H in the third brightest yellow, X02H in the second brightest yellow, X03H in the brightest yellow, and X04H in the darkest yellow, and the infrared communication device 32 sequentially transmits the control signals to all the lamps 10.

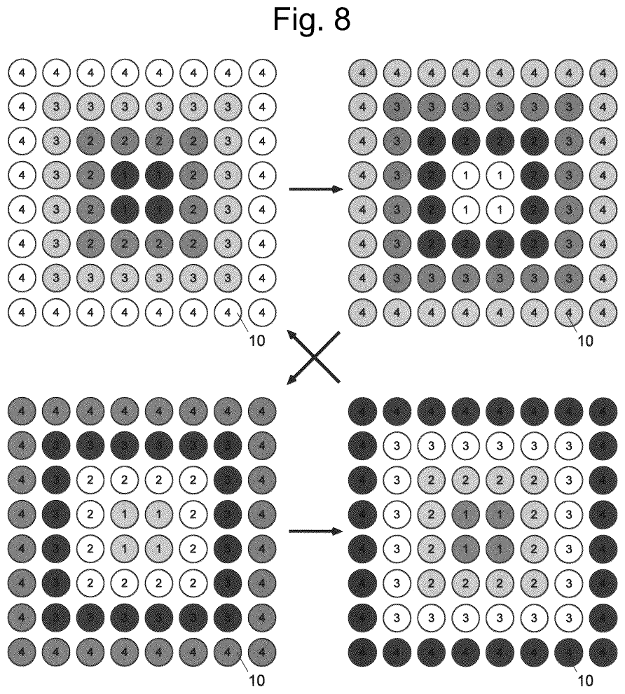

With the repeated operations described above, illumination is repeated such that the lamps 10 sequentially emit light in four patterns illustrated in FIG. 8 in the order of the upper left diagram, the upper right diagram, the lower left diagram, and the lower right diagram and the lamps 10 return to the pattern of the upper left diagram. With this illumination, it is possible to express the movement in which a yellow frame continues to spread from the inside to the outside.

In the above description, only the change in yellow brightness has been described, but in actual use, more complicated and beautiful illumination can be expressed by changing the color and brightness.

### (2) Second Embodiment

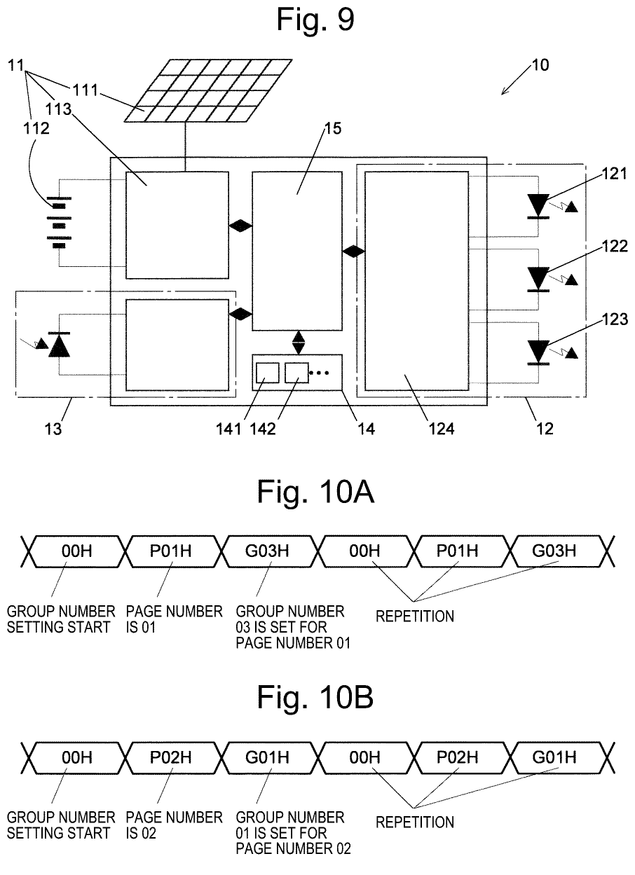

A lamp and an illumination system of the second embodiment have the same configuration as that of the first embodiment on hardware except that the nonvolatile memory (group number storage unit) 14 of the lamp 10 has a plurality of pages 141, 142, and so forth as illustrated in FIG. 9. The pages 141, 142, and so forth each store one group number. Therefore, the entire nonvolatile memory 14 stores a plurality of group numbers. Each of the pages 141, 142, and so forth have one group number of 01, 02, and so forth.

FIGS. 10A and 10B illustrate an example of signals generated by the personal computer 31 and transmitted by the infrared communication device 32 in the second embodiment. These signals give the lamps 10 that receive the signals one group number for each of a plurality of corresponding page numbers (accordingly, a plurality of group numbers are given to one lamp 10 as a whole), and are simultaneously transmitted to a plurality of lamps 10 for which the same combinations of page numbers and group numbers are to be set. With the group number setting signals illustrated in FIGS. 10A and 10B, a page number (hereinafter referred to as Ppp) is designated by a code following a program start code of “00H”, and a group number (hereinafter referred to as Gnn) is written by the next code.

In the example of FIG. 10A, a code “P01H” indicating a page number 01 is transmitted and then a code “G03H” indicating a group number 03 is transmitted. In the example of FIG. 10B, a code “P02H” indicating a page number 02 is transmitted and then a code “G01H” indicating a group number 01 is transmitted. In the lamp 10 that has received a series of infrared signals of FIGS. 10A and 10B, the group number 03 is stored in the page 141 of the page number 01, and the group number 01 is stored in the page 142 of the page number 02. Hereinafter, the group number stored in the page 141 of the page number 01 is described before “/” (slash), and the group number stored in the page 142 of the page number 02 is described after “/”. In the examples of FIGS. 10A and 10B, the above description is “03/01”. Note that, here, the number of pages is two, but may be three or more.

Also in the second embodiment, similarly to the first embodiment, in the group number setting operation described above, the lamps that have normally completed the instructed work (writing of the group number for each page number) may, for example, emit light of the green LED for a short time, and the lamps that have abnormality may emit light of the red LED for a long time.

By such a method, the total number of lamps 10 having a plurality of group numbers stored in the pages of the nonvolatile memory 14 are installed at a site where illumination is to be performed. In the example illustrated in FIG. 11, the lamps 10 are disposed similar to those in FIG. 6 with regard to the group numbers stored in the page 141 of the page number 01 and with regard to the group numbers stored in the page 142 of the page number 02, the lamps 10 are divided into four regions in a horizontal direction for each group number.

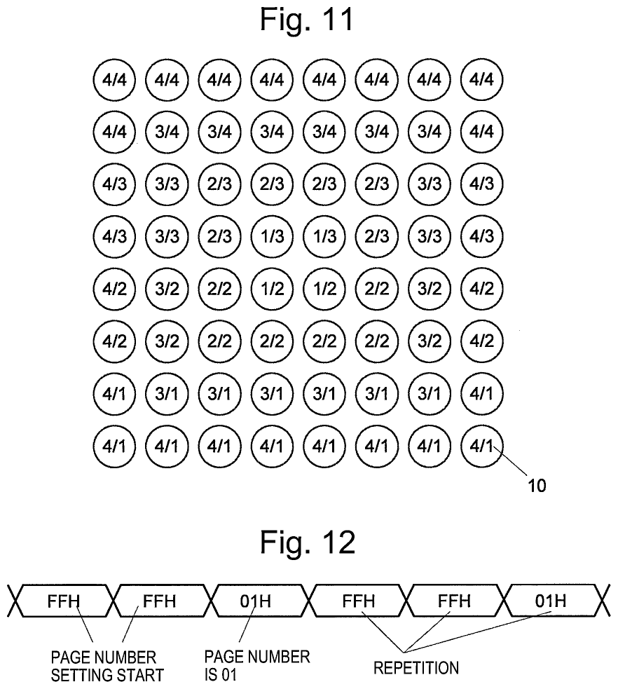

To cause the lamps 10 to emit light, firstly as illustrated in FIG. 12, the control start code of “FFH” and then the page selection code of “FFH” are transmitted, and subsequently a page number “01H” (or “02H”) is sent, and then a page number 01 (or 02) is designated.

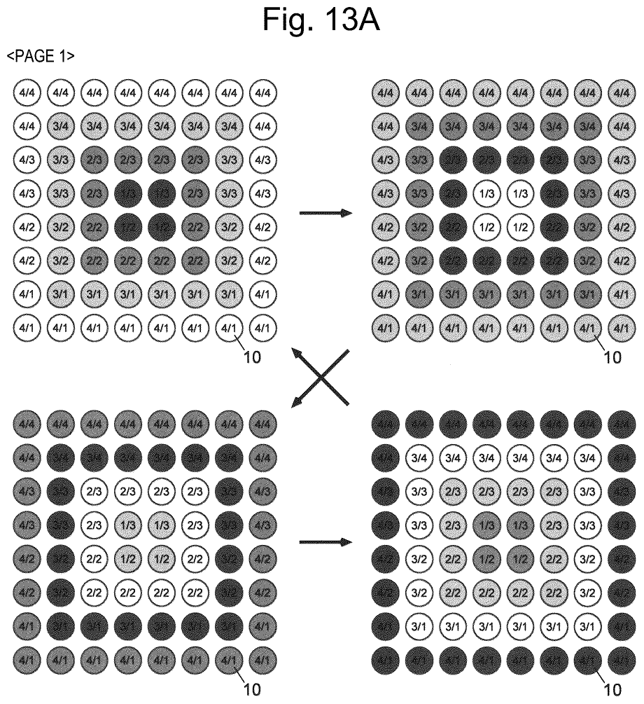

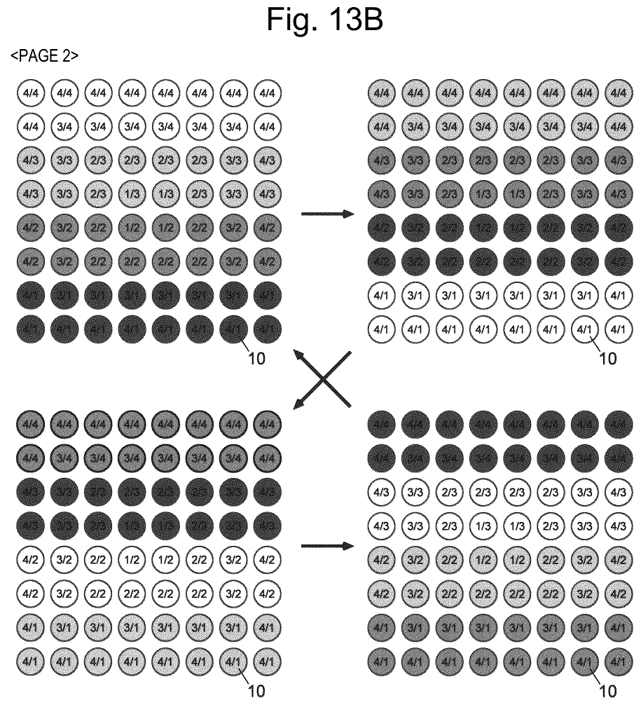

Thereafter, similarly to the case of the first embodiment, the lighting of each of the lamps 10 is controlled by transmitting a control signal including a control start signal, a group number designation signal, and a color-specific intensity designation signal for each group number (see FIG. 7). The lamps 10 that have received the control signal operate according to the group number assigned in the page number 01 when the page number 01 is designated, and operate according to the group number assigned in the page number 02 when the page number 02 is designated. In a case where the lamps 10 are disposed as illustrated in FIG. 11, when the page number 01 is designated, it is possible to express illumination in which a square frame moves outward or inward as illustrated in FIG. 13A, and when the page number 02 is designated, it is possible to express illumination in which horizontal linear illumination moves from the lower side to the upper side as illustrated in FIG. 13B. As described above, since illuminations having different patterns and movements can be instantaneously displayed only by switching page numbers, it is possible to provide a wide variety of illuminations that do not make viewers bored.

### (3) Third Embodiment

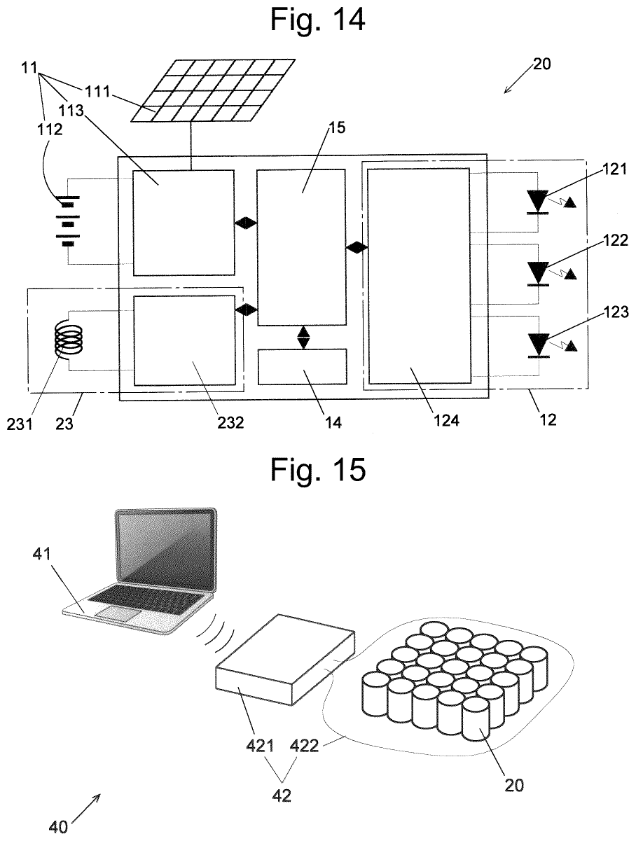

A third embodiment of the illumination system will be described below with reference to FIG. 14 and so forth. In the third embodiment, as the wireless communication unit included in the lamp 20, a magnetic communication reception circuit 23 is employed as illustrated in FIG. 14, instead of the infrared communication reception circuit 13 used in the first and second embodiments. Magnetic communication can be generally freely used unlike radio communication using radio waves that require permission and authorization according to the Radio Law, and detection of an AC magnetic field can be implemented with very low power consumption and at low cost by using an inexpensive coil, a Hall element that has been frequently used recently, or the like.

The magnetic communication reception circuit 23 includes a coil 231 and an amplification/demodulation circuit 232 for an AC signal obtained from the coil 231. Instead of the coil 231, magnetic detection elements such as various types of Hall elements and magnetoresistive elements can be used. Since the configuration of the lamp 20 other than the magnetic communication reception circuit 23 is similar to the configuration of the lamp 10 in the first and second embodiments, detailed description of them will be omitted.

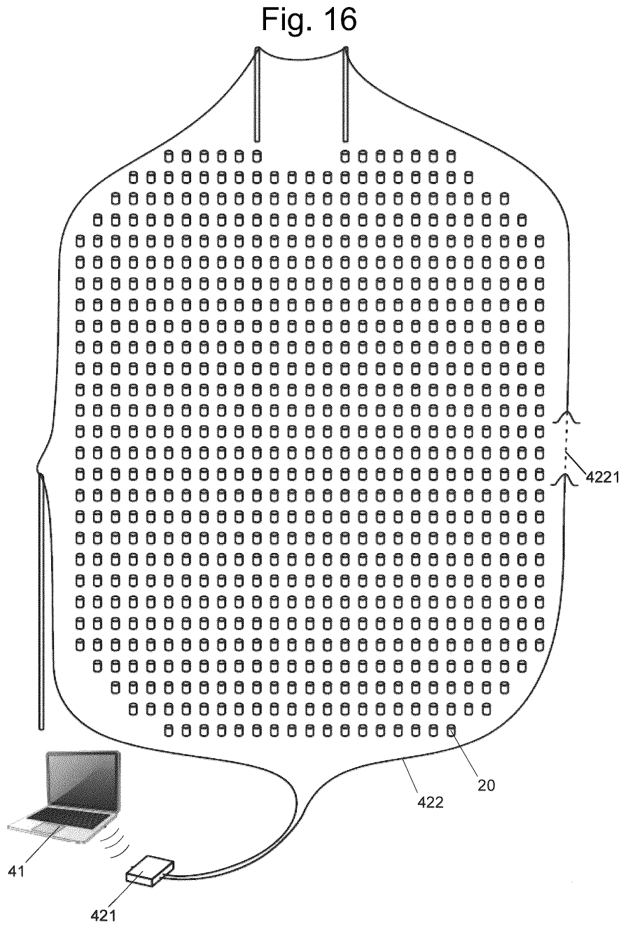

FIG. 15 illustrates an illumination system 40 in the third embodiment. In the illumination system 40, a personal computer 41 and a magnetic communication interface 421 are wirelessly connected, and a transmission loop 422 is connected to the magnetic communication interface 421. Note that, as in the first embodiment, the personal computer 41 and the magnetic communication interface 421 may be connected to each other by wire, but the installation work is easier when they are wirelessly connected to each other. A part or all of the transmission loop 422 may be buried in the ground. In the example illustrated in FIG. 16, a portion of the transmission loop 422 denoted by reference numeral 4221 is buried in the ground. A combination of the magnetic communication interface 421 and the transmission loop 422 is a magnetic communication device 42, which functions as the group number setting wireless communication device and the control information transmission wireless communication device. When an alternating current is caused to flow through the transmission loop 422, the magnetic communication reception circuit 23 of the lamps 20 placed inside the transmission loop 422 generates an AC signal and amplifies and demodulates the AC signal, whereby the lamps 20 can recognize the signal.

FIG. 16 illustrates an example of a case where a control signal is distributed by magnetic communication to all of a large number of lamps installed in a wide area. The magnetic communication interface 421 is wirelessly connected to the personal computer 41, and the transmission loop 422 is disposed so as to surround the area where the lamps 20 are installed. Note that, in this example, the personal computer 41 and the magnetic communication interface 421 may be connected to each other by wire, but the installation work is easier when they are wirelessly connected to each other. An AC signal is generated in the magnetic communication reception circuit 23 inside the lamp 20 by causing an alternating current to flow in the transmission loop 422, and the lamp 20 receives a control signal by amplification and demodulation of the AC signal.

When the transmission loop 422 is installed, the electric wire can be lifted up to a required height with a support or the like as illustrated in FIG. 16 or can be buried in the ground in a place where it is difficult to dispose an electric wire on the ground such as a passage, which ensures a high degree of freedom. In addition, in a case where the installation region is very large or the installation region is divided into blocks, the transmission loop may be divided into a plurality of transmission loops.

The group number setting operation and the control of the operation of each lamp 20 in the third embodiment are similar to those in the first or second embodiment except that magnetic communication is used, and thus detailed description is omitted.

### (4) Fourth Embodiment

### (4-1) Configuration of Speaker-Equipped Lamp and Illumination System of Fourth Embodiment

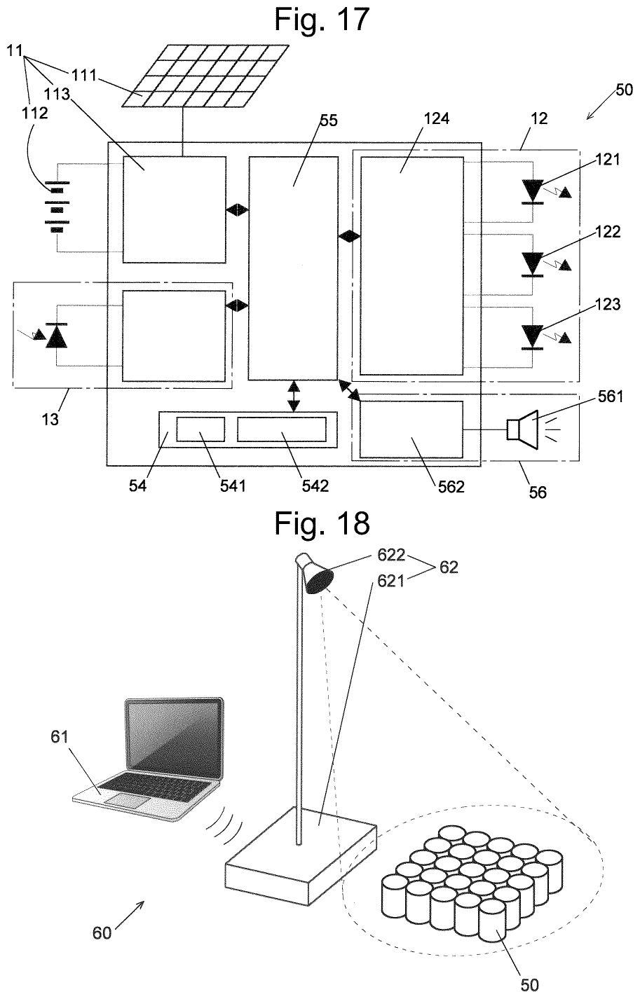

FIG. 17 is an embodiment related to a speaker-equipped lamp. This speaker-equipped lamp 50 includes a power supply unit 11, a light emitting unit 12, an infrared communication reception circuit (wireless communication unit) 13, a nonvolatile memory 54, a CPU circuit 55, and a sound producing unit 56. Since the power supply unit 11, the light emitting unit 12, and the infrared communication reception circuit 13 are similar to those of the lamp 10 of the first embodiment, detailed description of them will be omitted.

The sound producing unit 56 includes a speaker 561 and a sound producing circuit 562. In the present embodiment, only one speaker 561 is provided for each speaker-equipped lamp 50, but two or more speakers may be provided. The sound producing circuit 562 is a circuit configured to convert a control signal from the CPU circuit 55 into an electric signal which causes the speaker 561 to produce sound, and has a function such as an amplifier.

The nonvolatile memory 54 is structurally the same as the nonvolatile memory 14 in the first embodiment, and includes a group number storage unit 541 which stores a group number and a sound data storage unit 542 which stores sound data as functional blocks. The sound data storage unit 542 stores a plurality of pieces of sound data. Each piece of sound data includes waveform data within a predetermined sound production time. A sound data number, which is a number to be distinguished from other sound data, is given to each piece of sound data. Each of the sound data numbers is stored in the sound data storage unit 542, in association with the corresponding sound data. Note that the sound data and the sound data number transmitted from the infrared communication device 32 may be received by the infrared communication reception circuit 13 and then stored in the sound data storage unit 542, or the speaker-equipped lamp 50 may be further provided with a wireless or wired communication interface different from the infrared communication reception circuit 13, and the sound data and the sound data number may be received by the communication interface and then stored in the sound data storage unit 542. In particular, in a case of using sound data with a long time like music, it is preferable to use a communication interface capable of transmitting and receiving data with a larger capacity than the infrared communication device 32 and the infrared communication reception circuit 13.

Examples of the sound to be stored in the sound data storage unit 542 as sound data include natural sounds such as waves and wind sounds, animal voices such as insects and birds, sounds of musical instruments, and human voices (including singing voice). For example, different sound data numbers can be assigned to different animal sounds, different instrument sounds, and different parts (soprano, alto, etc.) for human singing sounds.

The CPU circuit 55 is structurally the same as the CPU circuit 15 in the first embodiment, and is a control unit configured to collectively control the power supply unit 11, the light emitting unit 12, the infrared communication reception circuit 13, the nonvolatile memory 54, and the sound producing unit 56. As in the case of the first embodiment, (a plurality of) control units that individually control each unit may be used.

As shown in FIG. 18, the illumination system of the fourth embodiment includes a plurality of speaker-equipped lamps 50, a personal computer 61, and an infrared communication device 62 having an infrared communication interface 621 and an infrared communication signal transmission unit 622 and wirelessly connected to the personal computer 61. The personal computer 61 and the infrared communication device 62 are similar to the personal computer 31 and the infrared communication device 32 in the illumination system of the first embodiment except that control information related to sound is generated and transmitted in addition to light. In addition, in the fourth embodiment, similarly to the example illustrated in FIG. 3 in the first embodiment, it is possible to control all the speaker-equipped lamps 50 by installing a large number of speaker-equipped lamps 50 in a wide area and disposing a plurality of infrared communication signal transmission units.

### (4-2) Operation of Speaker-Equipped Lamp and Illumination System of Fourth Embodiment

Hereinafter, operation of the speaker-equipped lamps 50 and an illumination system 60 according to the fourth embodiment will be described. In the fourth embodiment, firstly an operation of setting a group number for each of the speaker-equipped lamps 50 is performed. Thereafter, lighting and sound production of each of the speaker-equipped lamps 50 are controlled to generate illumination with change and realistic sound. Since the group number setting operation is the same as the operation described with reference to FIGS. 4A to 4D to FIG. 6 in the first embodiment, the description is omitted, and control of lighting and sound production of each of the speaker-equipped lamps 50 will be described below.

To cause the speaker-equipped lamps 50 to emit light and produce sound, the following control signal is generated by the personal computer 61, and then the control signal is transmitted from the infrared communication device 62 to all the speaker-equipped lamps 50. First, the control start signal “FFH” is transmitted and then the group number designation signal “XnnH” for designating a group number “nn” is transmitted. Next, color-specific intensity designation signals “RmmH”, “GmmH”, and “BmmH” indicating the emission intensities of red, green, and blue, respectively, as numerical values of hexadecimal digits “mm” (actually, numerical values are set for each color) are transmitted in this order. Next, a sound designation signal “ShkH” for designating a sound data number “hk” of sound data to be produced is transmitted.

In a case where the sound data is a musical instrument music, a singing voice, or the like, it is also possible to assign different musical instruments or parts to different groups, and then assign a (lower digit of) group number to a first number “h” of the sound data number “hk”, and assign a number of a sound production order of the sound data for each time to a subsequent number “k”.

Through the operations described above, the transmission of the control signal for lighting and sound production to the speaker-equipped lamps 50 having a certain group number is completed. To subsequently transmit the control signal to the speaker-equipped lamps 50 having another group number, firstly the control start signal “FFH” is transmitted, and then the group number designation signal, the color-specific intensity designation signal for three colors, and the sound designation signal are transmitted. By performing this operation on all the group numbers, the transmission of the control signal is completed.

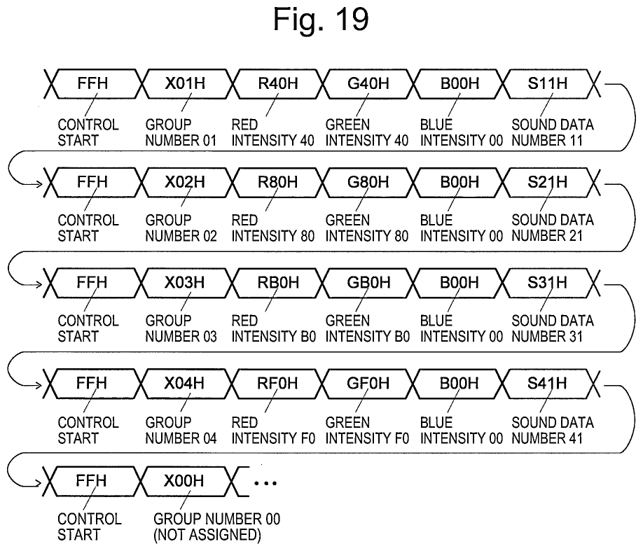

FIG. 19 illustrates an example of the control signal. In this example, after the control start signal “FFH” is transmitted, the group number designation signal “X01H” and the color-specific intensity designation signals “R40H”, “G40H”, and “B00H”, and the sound designation signal “S11H” are transmitted. These control signals mean that the speaker-equipped lamps 50 to which the group number 01 is assigned are caused to emit light such that the red has an intensity of the 64th level, the green has an intensity of the 64th level, and the blue has an intensity of 0, and produce sound according to the sound data to which the sound data number 11 is assigned. Next, the control start signal “FFH”, the group number designation signal “X02H”, the color-specific intensity designation signals “R80H”, “G80H”, and “B00H”, and the sound designation signal “S21H” are transmitted. Subsequently, the control start signal “FFH”, the group number designation signal “X03H”, the color-specific intensity designation signals “RB0H”, “GB0H”, and “B00H”, and the sound designation signal “S31H” are transmitted. Finally, the control start signal “FFH”, the group number designation signal “X04H”, the color-specific intensity designation signals “RF0H”, “GF0H”, and “B00H”, and the sound designation signal “S41H” are transmitted.

With the control signal transmitted as shown in FIG. 19, the light emitting unit 12 of the speaker-equipped lamps 50 emits light of “the darkest yellow” in which the red has an intensity of the 64th level, the green has an intensity of the 64th level, and the blue has an intensity of 0 for the group number 01, emits light of “the third brightest yellow” in which the red has an intensity of the 128th level, the green has an intensity of the 128th level, and the blue has an intensity of 0 for the group number 02, emits light of “the second brightest yellow” in which the red has an intensity of the 176th level, the green has an intensity of the 176th level, and the blue has an intensity of 0 for the group number 03, and emits light of “the brightest yellow” in which the red has an intensity of the 240th level, the green has an intensity of the 240th level, and the blue has an intensity of 0 for the group number 04. As a result, the same light-emitting pattern as that shown in the upper left diagram of FIG. 8 is seen by viewers.

At the same time, the sound producing unit 56 of the speaker-equipped lamps 50 emits sound according to the sound data to which the sound data number 11 is assigned for the group number 01, emits sound according to the sound data to which the sound data number 21 is assigned for the group number 02, emits sound according to the sound data to which the sound data number 31 is assigned for the group number 03, and emits sound according to the sound data to which the sound data number 41 is assigned for the group number 04. As a result, a first superimposed sound in which these four types of sound generated from different positions are superimposed is heard by the viewers.

Next, after the time (generally one to several seconds) designated by a program has elapsed from the transmission of the first control signal, the personal computer 61 and the infrared communication device 62 generate and transmit to the speaker-equipped lamps 50, by the same method as described above, a total of four types of color-specific intensity designation signals for causing the speaker-equipped lamps 50 to emit light of the brightest yellow on X01H, the darkest yellow on X02H, the third brightest yellow on X03H, and the second brightest yellow on X04H, and also generate and transmit to the speaker-equipped lamps 50 a total of four types of sound designation signals of a sound designation signal “S12H” on X01H, a sound designation signal “S22H” on X02H, a sound designation signal “S32H” on X03H, and a sound designation signal “S42H” on X04H. As a result, the same light-emitting pattern as that shown in the upper right diagram of FIG. 8 is seen by the viewers. At the same time, a second superimposed sound in which the four types of sound according to the sound data assigned with the sound data numbers 12, 22, 32, and 42 are superimposed is heard by the viewers.

Furthermore, after the time designated by the program has elapsed, the personal computer 61 and the infrared communication device 62 generate and transmit to the speaker-equipped lamps 50, by the same method as described above, a total of four types of color-specific intensity designation signals for causing the speaker-equipped lamps 50 to emit light of the second brightest yellow on X01H, the brightest yellow on X02H, the darkest yellow on X03H, and the third brightest yellow on X04H, and also generate and transmit to the speaker-equipped lamps 50 a total of four types of sound designation signals of a sound designation signal “S13H” on X01H, a sound designation signal “S23H” on X02H, a sound designation signal “S33H” on X03H, and a sound designation signal “S43H” on X04H. Thereafter, after the time designated by the program has elapsed, the personal computer 61 and the infrared communication device 62 generate and transmit to the speaker-equipped lamps 50, by the same method as described above, a total of four types of color-specific intensity designation signals for causing the speaker-equipped lamps 50 to emit light of the third brightest yellow on X01H, the second brightest yellow on X02H, the brightest yellow on X03H, and the darkest yellow on X04H, and also generate a total of four types of sound designation signals of a sound designation signal “S14H” on X01H, a sound designation signal “S24H” on X02H, a sound designation signal “S34H” on X03H, and a sound designation signal “S44H” on X04H. Through these operations, the same two light emission patterns as those illustrated in the lower left diagram and the lower right diagram of FIG. 8 are sequentially seen by the viewers. At the same time, a third superimposed sound in which four types of sound according to the sound data assigned with the sound data numbers 13, 23, 33, and 43 are superimposed and a fourth superimposed sound in which four types of sound according to the sound data assigned with the sound data numbers 14, 24, 34, and 44 are superimposed are sequentially heard by the viewers.

With the repeated operations described above, illumination is repeated such that the speaker-equipped lamps 50 sequentially emit light in four patterns illustrated in FIG. 8 in the order of the upper left diagram, the upper right diagram, the lower left diagram, and the lower right diagram and the speaker-equipped lamps 50 return to the pattern of the upper left diagram. In synchronization with the repetition of the illumination, the first superimposed sound, the second superimposed sound, the third superimposed sound, and the fourth superimposed sound are sequentially produced, and the sound returns to the first superimposed sound.

In a case where different musical instruments or parts of the sound data are assigned to different groups from each other and the (lower digit of) group number “h” (1 to 4) and the number “k” (1 to 4) indicating the sound order make the sound data number “hk” (11 to 14, 21 to 24, 31 to 34, 41 to 44), sounds of the different musical instruments or the singing voice of the parts are emitted from the speaker-equipped lamps 50 belonging to each group according to the sound order.

In the above description, only the change in yellow brightness has been described, but in actual use, more complicated and beautiful illumination can be expressed by changing the color and brightness.

### (5) Fifth Embodiment

As described above, in the fourth embodiment, since the light emission by the light emitting unit 12 and the sound production by the sound producing unit 56 are controlled using the same group number, the speaker-equipped lamps 50 that emit the same light produce the same sound. On the other hand, a speaker-equipped lamp and an illumination system of a fifth embodiment have the following configurations in order to independently control light emission unit and sound production unit.

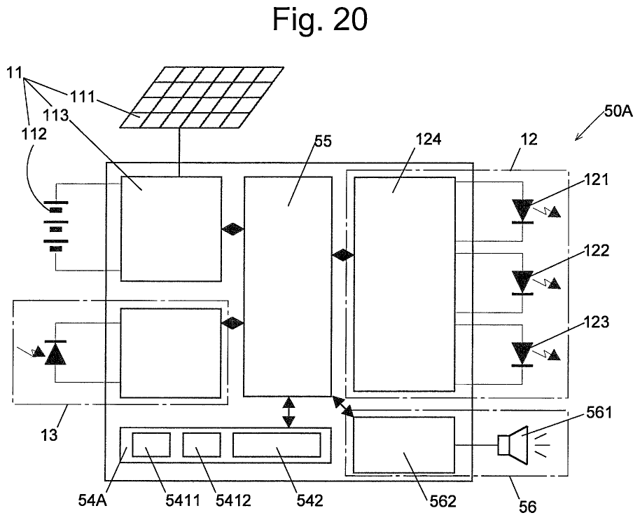

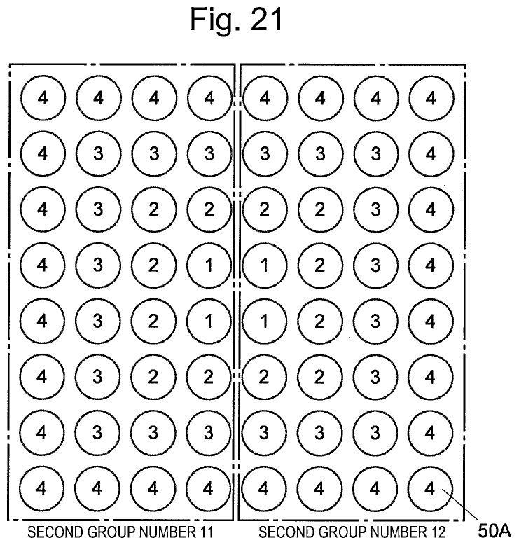

FIG. 20 illustrates a configuration of a speaker-equipped lamp 50A of the fifth embodiment. The speaker-equipped lamp 50A includes a nonvolatile memory 54A having functions as a first group number storage unit 5411, a second group number storage unit 5412, and a sound data storage unit 542 instead of the nonvolatile memory 54 having functions as the group number storage unit 541 and the sound data storage unit 542 in the speaker-equipped lamp 50 of the fourth embodiment. Other configurations of the speaker-equipped lamp 50A are similar to those of the speaker-equipped lamp 50 of the fourth embodiment.

A first group number is stored in the first group number storage unit 5411, and a second group number is stored in the second group number storage unit 5412. Both the first group number and the second group number are generated by the personal computer 61 as described later, transmitted by the infrared communication device 62, and received by the infrared communication reception circuit 13 of the speaker-equipped lamp 50A. The first group number is a number for discriminating a group of the speaker-equipped lamps 50A for causing the light emitting unit 12 to execute the same operation, and the second group number is a number for discriminating a group of the speaker-equipped lamps 50A for causing the sound producing unit 56 to execute the same operation.

In each of the speaker-equipped lamps 50A, the first group number and the second group number are given independently of each other. In the example illustrated in FIG. 21, first group numbers of 01 to 04 (indicated as “1” to “4” in the drawing) are assigned concentrically to a large number of the speaker-equipped lamps 50A disposed in a square lattice shape, and a second group number of 11 is assigned to the left half and 12 is assigned to the right half. Of course, the method of dividing the first group and the second group is not limited to this example. The number of groups in each of the first group and the second group is also not limited to this example (the former is four and the latter is two).

The illumination system of the fifth embodiment includes, as hardware, the personal computer 61 and the infrared communication device 62 similar to those of the illumination system of the fourth embodiment illustrated in FIG. 18, and is formed by combining them with the speaker-equipped lamps 50A of the fifth embodiment. In the present embodiment, the personal computer 61 has a function of generating a first control signal for controlling the operation of the light emitting unit 12 for each first group number and a function of generating a second control signal for controlling the operation of the sound producing unit 56 for each second group number. The infrared communication device 62 transmits the first control signal and the second control signal to the infrared communication reception circuit 13 of the speaker-equipped lamps 50A.

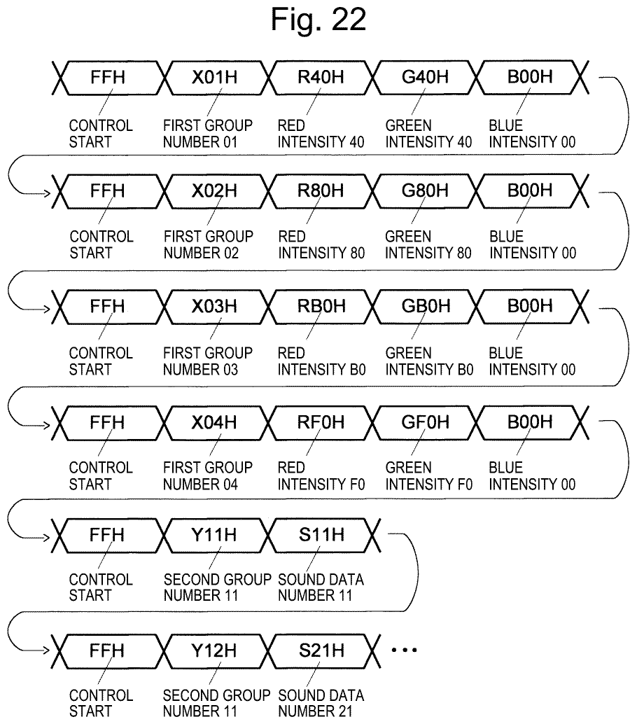

FIG. 22 illustrates an example of the first and second control signals. The first to fourth rows among the control signals of the six rows illustrated in the drawing are first control signals for controlling the light emitting unit 12, and these are signals for controlling the light emission intensities of the red LED element 121, the green LED element 122, and the blue LED element 123 for the four first groups 01 to 04, respectively, similarly to the control signals of the first embodiment (FIG. 7). The fifth and sixth rows are second control signals for controlling the sound producing unit 56, which are transmitted subsequent to the first control signals. Specifically, the second control signals control the speaker-equipped lamps 50A to which the second group number 11 is assigned among the two second groups to produce sound 11 according to the sound data assigned with the sound data number 11, and control the speaker-equipped lamps 50A to which the second group number 12 is assigned to produce sound 21 according to the sound data assigned with the sound data number 21. The first control signal and the second control signal are also not limited to this example.

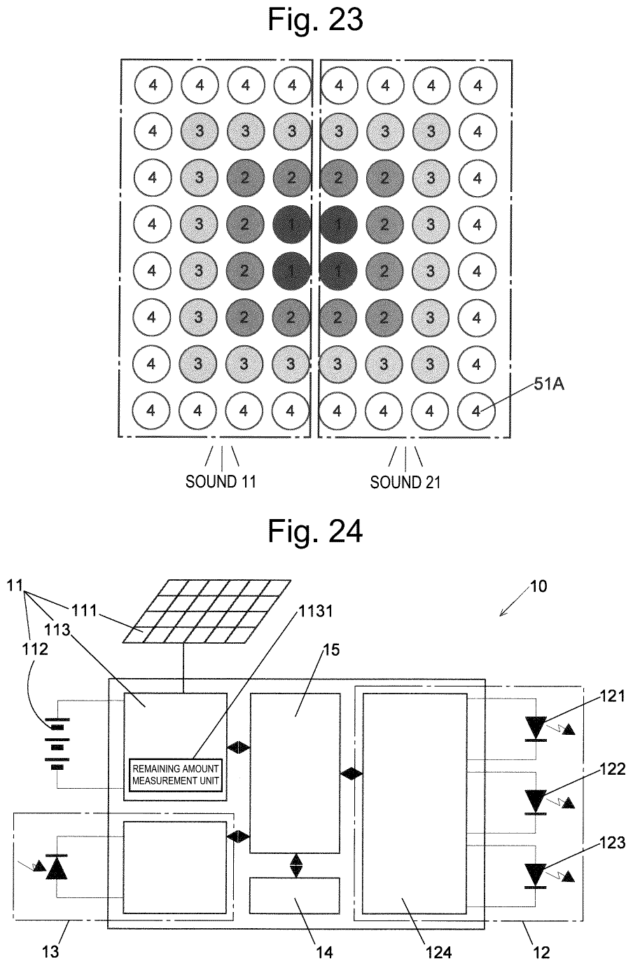

In response to the first control signal and the second control signal, each of the speaker-equipped lamps 50A causes the light emitting unit 12 to emit light according to the first control signal corresponding to the first group to which the speaker-equipped lamp 50A belongs, and causes the sound producing unit 56 to produce sound according to the second control signal corresponding to the second group. In a case where the first control signal and the second control signal of the example illustrated in FIG. 22 are transmitted to the speaker-equipped lamps 50A grouped in the example illustrated in FIG. 21, the speaker-equipped lamps 50A emit light with different intensities for each of the first groups 01 to 04 (“1” to “4” in the drawing) and emit different sounds for each of the second groups 11 and 12, as illustrated in FIG. 23.

Thereafter, with the transmission of the first control signal and/or the second control signal having different contents, the light emission of the speaker-equipped lamps 50A of the first group and/or the sound production of the speaker-equipped lamps 50A of the second group can be changed.

### (7) Operations and Effects of Each Embodiment

As described above, in the entertainment apparatus and the entertainment system of each of the above embodiments, since the entertainment apparatus uses the wireless communication function of simple and low power consumption having only the reception function, the entire entertainment system is inexpensive and low power consumption, and thus, it is possible to drive the entertainment apparatus and the entertainment system for a long time by a battery. In addition, it is possible to express various kinds of complicated movements that do not viewers get bored in a large number of large-scale full color illuminations installed in a wide range. In addition, in the fourth and fifth embodiments, it is possible to realize a realistic sound by providing speakers to the large number of entertainment apparatuses installed in a wide range and dividing them into a plurality of groups and causing them to produce different sounds for each group.

In the above embodiments, the entertainment apparatuses each have the same hardware and software. This configuration, when they are used for a large-scale illumination including thousands of or tens of thousands of entertainment apparatuses, makes it possible to collectively write the control information or the like only by dividing them into groups, and also makes the installation work easy since installation does not relate to individual entertainment apparatuses as long as they are in the same group.

In addition, even at the time of actual use (at the time of lighting), since conventional lamps individually have identification numbers, the communication volume becomes enormous as the number increases, and high-speed communication is required. However, since the entertainment apparatus according to the present invention can be collectively controlled in each group, the amount of data can be greatly reduced, which enables large-scale illumination with movement even in low-speed communication.

Furthermore, in the case of having a page function as in the second embodiment, since the page can be collectively switched for all the entertainment apparatuses, it is possible to instantaneously switch and express the illumination of various patterns.

### (8) Modifications

The present invention is not limited to the above embodiments, and various variations are possible.

For example, in the description of each of the above embodiments, the setting of the page number, the group number, the power of the red LED, the green LED, and the blue LED, and the like has been described as 8 bits in a binary number. However, in order to increase the communication speed at the time of use, each of them may be represented by 4 bits, or 8 bits and 4 bits may be appropriately combined and used. The code system in the above embodiments is an example, and does not affect the effects of the invention at all.

In each of the above embodiments, the solar panel and the secondary battery are used for the power supply unit, but a simple secondary battery or a primary battery may be used. Power may be supplied by wire. In addition, in each of the above embodiments, the LED is used as a light source, but a light source other than the LED may be used. In each of the above embodiments, infrared communication (first to fourth embodiments) or magnetic communication (third embodiment) is used as a wireless communication device, but other wireless communication devices may be used.

In the second embodiment, the lamp 10 (not including a speaker) is controlled using the page function, but the control may also be performed on the speaker-equipped lamp 50 using the page function as in the second embodiment. In this case, firstly as a preparatory stage, as in the example illustrated in FIGS. 10A and 10B in the second embodiment, the group numbers are stored in the pages (corresponding to the pages 141, 142, and so forth in the second embodiment) of the nonvolatile memory 54 of each of the speaker-equipped lamps 50 by using wireless communication, for the corresponding page numbers of the pages. Then, when the illumination is performed, firstly as in the example illustrated in FIG. 12 in the second embodiment, the page number is transmitted to the speaker-equipped lamps 50 by using wireless communication. As a result, each of the speaker-equipped lamps 50 reads the group number stored in the received page number. Thereafter, based on the group number, similarly to the fourth embodiment, each of the speaker-equipped lamps 50 receives a signal of control information including the operations of the light emitting unit 12 and the sound producing unit 56 designated by the group number by wireless communication, and then executes the operations.

In the fourth and fifth embodiments and the modification of the second embodiment described in the preceding paragraph, the speaker-equipped lamp 50 is used and the operation of both the light emitting unit 12 and the sound producing unit 56 included in the speaker-equipped lamp 50 is controlled, but a speaker not including the light emitting unit 12 (including the sound producing unit 56) may be used instead of the speaker-equipped lamp 50. In this case, the speaker is controlled such that the operation of transmitting the control signal related to the control of the light emitting unit 12 is omitted from the operation in the fourth or fifth embodiment or the modification of the second embodiment.

In the embodiments and the modifications above, a remaining amount measurement unit 1131 that measures the remaining amount of the battery may be further provided in the power supply circuit 113, and the CPU circuit 15 may function as an output control unit that acquires the remaining amount measured by the remaining amount measurement unit 1131 and performs control to reduce the output of the light emitting unit 12 and/or the sound producing unit 56 when the remaining amount is equal to or less than a predetermined value. Although FIG. 24 illustrates an example in which the remaining amount measurement unit 1131 is provided in the configuration of the first embodiment, a similar remaining amount measurement unit can be provided in other embodiments and modifications. With such a configuration, it is possible to extend the time before the lamp 10 or the speaker-equipped lamps 51, 51A stop due to what is called battery exhaustion, and it is possible to prevent the lamp or the like from stopping by securing the time for replacement of the primary battery or charging of the secondary battery.

### MODES

A person skilled in the art can understand that the previously described illustrative embodiments are specific examples of the following modes of the present invention.

(Clause 1) An entertainment apparatus according to Clause 1 includes:
a) an entertainment presentation unit having one or both of a light emitting unit capable of emitting a plurality of types of light and a sound producing unit capable of producing sound;
b) a group number storage unit configured to store a group number;
c) a wireless communication unit configured to wirelessly receive control information for controlling an operation of the entertainment presentation unit assigned to the group number; and
d) a control unit configured to control one or both of light emission and sound production of the entertainment presentation unit based on the control information received by the wireless communication unit and the group number stored in the group number storage unit.

(Clause 2) An entertainment apparatus according to Clause 2 is the entertainment apparatus according to Clause 1, in which the wireless communication unit is further configured to wirelessly receive the group number.

(Clause 3) An entertainment apparatus according to Clause 3 is the entertainment apparatus according to Clause 1 or 2, in which the group number storage unit includes a plurality of pages each of which stores a group number.

(Clause 4) An entertainment apparatus according to Clause 4 is the entertainment apparatus according to any one of Clauses 1 to 3, in which
the operation of the entertainment presentation unit assigned to the group number is an operation of one of the light emitting unit and the sound producing unit,
the group number storage unit is further configured to store a second group number,
the wireless communication unit is further configured to wirelessly receive second control information for controlling the operation of another one of the light emitting unit and the sound producing unit assigned to the second group number, and
the control unit is configured to control the operation of the one of the light emitting unit and the sound producing unit based on the control information and the group number stored in the group number storage unit, and control the operation of the another one of the light emitting unit and the sound producing unit based on the second control information and the second group number stored in the group number storage unit.

(Clause 5) An entertainment apparatus according to Clause 5 is the entertainment apparatus according to any one of Clauses 1 to 4, further including:
a primary battery or a secondary battery configured to supply power to the light emitting unit;
a remaining amount measurement unit configured to measure a remaining amount of the primary battery or the secondary battery; and
an output control unit configured to perform control to reduce output of the entertainment presentation unit when a remaining amount measured by the remaining amount measurement unit is equal to or less than a predetermined value.

(Clause 6) An entertainment apparatus according to Clause 6 is the entertainment apparatus according to any one of Clauses 1 to 5, further including a power supply unit including a solar power generation panel and a secondary battery configured to supplying power to the light emitting unit.

(Clause 7) An entertainment system according to Clause 7 includes:
a plurality of entertainment apparatuses each including an entertainment presentation unit having one or both of a light emitting unit capable of emitting a plurality of types of light and a sound producing unit capable of producing sound, a group number storage unit configured to store a group number, a wireless communication unit configured to wirelessly receive control information for controlling an operation of the entertainment presentation unit assigned to the group number, and a control unit configured to control one or both of the light emitting unit and the sound producing unit of the entertainment presentation unit based on the control information received by the wireless communication unit and the group number stored in the group number storage unit;
an information generation device configured to generate the control information for each of the group numbers assigned to the plurality of entertainment apparatuses; and
a control information transmission wireless communication device configured to wirelessly transmit the control information for the group numbers generated by the information generation device to all of the plurality of entertainment apparatuses.

(Clause 8) An entertainment system according to Clause 8 is the entertainment system according to Clause 7, in which
the wireless communication unit is further configured to wirelessly receive the group number, and
the information generation device is further configured to generate the group numbers,
the entertainment system further including a group number setting wireless communication device configured to transmit, by wireless communication, the same group number generated by the information generation device to all the entertainment apparatuses belonging to the same group among the plurality of entertainment apparatuses.

(Clause 9) An entertainment system according to Clause 9 is the entertainment system according to Clause 7, in which
the group number storage unit includes a plurality of pages each having a page number and storing a group number, and
the control information transmission wireless communication device is configured to transmit the page number and the control information.

(Clause 10) An entertainment system according to Clause 10 is the entertainment system according to Clause 8, in which the group number storage unit includes a plurality of pages each having a page number and storing a group number,
the wireless communication unit is further configured to wirelessly receive the page number,
the group number setting wireless communication device is configured to transmit the page number and the group number, and
the control information transmission wireless communication device is configured to transmit the page number and the control information.

(Clause 11) An entertainment system according to Clause 11 is the entertainment system according to any one of Clauses 7 to 10, in which
the entertainment presentation unit includes both the light emitting unit and the sound producing unit, and the operation of the entertainment presentation unit assigned to the group number is an operation of one of the light emitting unit and the sound producing unit,
the group number storage unit is further configured to store a second group number,
the wireless communication unit is further configured to wirelessly receive second control information for controlling the operation of another one of the light emitting unit and the sound producing unit assigned to the second group number,
the control unit is configured to control the operation of the one of the light emitting unit and the sound producing unit based on the control information and the group number stored in the group number storage unit, and control the operation of the other one of the light emitting unit and the sound producing unit based on the second control information and the second group number stored in the group number storage unit,
the information generation device is further configured to generate the second control information for the second group number, and
the control information transmission wireless communication device is further configured to wirelessly transmit the second control information to all of the plurality of entertainment apparatuses.

(Clause 12) An entertainment system according to Clause 12 is the entertainment system according to any one of Clauses 7 to 11, in which the wireless communication is communication using infrared rays.

(Clause 13) An entertainment system according to Clause 13 is the entertainment system according to any one of Clauses 7 to 12, in which the wireless communication is communication using magnetism.

### REFERENCE SIGNS LIST

10, 20 . . . Lamp (Entertainment Apparatus)
11 . . . Power Supply Unit
111 . . . Solar Power Generation Panel
112 . . . Secondary Battery
113 . . . Power Supply Circuit
1131 . . . Remaining Amount Measurement Unit
12 . . . Light Emitting Unit
121 . . . Red LED Element
122 . . . Green LED Element
123 . . . Blue LED Element
124 . . . LED Lighting Circuit
13, 53 . . . Infrared Communication Reception Circuit (Wireless Communication Unit)
14 . . . Nonvolatile Memory (Group Number Storage Unit)
15, 55 . . . CPU Circuit
23 . . . Magnetic Communication Reception Circuit (Wireless Communication Unit)
231 . . . Coil
232 . . . Amplification/Demodulation Circuit
30, 40, 60 . . . Illumination System
31, 41, 61 . . . Personal Computer
32, 62 . . . Infrared Communication Device (Group Number Setting Wireless Communication Device and Control Information Transmission Wireless Communication Device)
321, 621 . . . Infrared Communication Interface
322, 3221 to 3224, 622 . . . Infrared Communication Signal Transmission Unit
33 . . . Region Irradiated with Infrared Rays
42 . . . Magnetic Communication Device (Group Number Setting Wireless Communication Device and Control Information Transmission Wireless Communication Device)
421 . . . Magnetic Communication Interface
422 . . . Transmission Loop
4221 . . . Portion of Transmission Loop Buried in Ground
50, 50A . . . Speaker-Equipped Lamp
54, 54A . . . Nonvolatile Memory
541 . . . Group Number Storage Unit
5411 . . . First Group Number Storage Unit
5412 . . . Second Group Number Storage Unit
542 . . . Sound Data Storage Unit
56 . . . Sound Producing Unit
561 . . . Speaker
562 . . . Sound Producing Circuit

1. An entertainment apparatus comprising:
a) an entertainment presentation unit having one or both of a light emitting unit capable of emitting a plurality of types of light and a sound producing unit capable of producing sound;
b) a group number storage unit configured to store a group number;
c) a wireless communication unit configured to wirelessly receive a plurality of control information for controlling an operation of the entertainment presentation unit assigned to each of a plurality of group numbers transmitted by a same control information transmission wireless communication device; and
d) a control unit configured to extract control information assigned to the group number stored in the group number storage unit from the plurality of control information received by the wireless communication unit and to control one or both of the light emitting unit and the sound producing unit of the entertainment presentation unit based on the control information extracted,
wherein the entertainment apparatus does not have an individual identification information.

2. The entertainment apparatus according to claim 1, wherein the wireless communication unit is further configured to wirelessly receive the group number.

3. The entertainment apparatus according to claim 1, wherein the group number storage unit includes a plurality of pages each of which stores a group number.

4. The entertainment apparatus according to claim 1, wherein
the operation of the entertainment presentation unit assigned to the group number is an operation of one of the light emitting unit and the sound producing unit,
the group number storage unit is further configured to store a second group number,
the wireless communication unit is further configured to wirelessly receive second control information for controlling the operation of another one of the light emitting unit and the sound producing unit assigned to the second group number, and
the control unit is configured to control the operation of the one of the light emitting unit and the sound producing unit based on the control information and the group number stored in the group number storage unit, and control the operation of the another one of the light emitting unit and the sound producing unit based on the second control information and the second group number stored in the group number storage unit.

5. The entertainment apparatus according to claim 1, further comprising:
a primary battery or a secondary battery configured to supply power to the entertainment presentation unit;
a remaining amount measurement unit configured to measure a remaining amount of the primary battery or the secondary battery; and
an output control unit configured to perform control to reduce output of the entertainment presentation unit when a remaining amount measured by the remaining amount measurement unit is equal to or less than a predetermined value.

6. The entertainment apparatus according to claim 1, further comprising a power supply unit including a solar power generation panel and a secondary battery configured to supplying power to the entertainment presentation unit.

7. An entertainment system comprising:
a plurality of entertainment apparatuses each including an entertainment presentation unit having one or both of a light emitting unit capable of emitting a plurality of types of light and a sound producing unit capable of producing sound, a group number storage unit configured to store a group number, a wireless communication unit configured to wirelessly receive a plurality of control information for controlling an operation of the entertainment presentation unit assigned to each of a plurality of group numbers, and a control unit configured to extract control information assigned to the group number stored in the group number storage unit from the plurality of control information received by the wireless communication unit and to control one or both of the light emitting unit and the sound producing unit of the entertainment presentation unit based on the control information extracted, wherein the plurality of entertainment apparatuses do not have individual identification information;
an information generation device configured to generate the plurality of control information; and
a control information transmission wireless communication device configured to wirelessly transmit the plurality of control information generated by the information generation device to all of the plurality of entertainment apparatuses.

8. The entertainment system according to claim 7, wherein
the wireless communication unit is further configured to wirelessly receive the group number, and
the information generation device is further configured to generate the group number,
the entertainment system further comprising a group number setting wireless communication device configured to transmit, by wireless communication, a same group number generated by the information generation device simultaneously to all entertainment apparatuses belonging to a same group among the plurality of entertainment apparatuses.

9. The entertainment system according to claim 7, wherein
the group number storage unit includes a plurality of pages each having a page number and storing a group number, and
the control information transmission wireless communication device is configured to transmit the page number and the control information.

10. The entertainment system according to claim 8, wherein
the group number storage unit includes a plurality of pages each having a page number and storing a group number,
the wireless communication unit is further configured to wirelessly receive the page number,
the group number setting wireless communication device is configured to transmit the page number and the group number, and
the control information transmission wireless communication device is configured to transmit the page number and the control information.

11. The entertainment system according to claim 7, wherein
the entertainment presentation unit includes both the light emitting unit and the sound producing unit, and the operation of the entertainment presentation unit assigned to the group number is an operation of one of the light emitting unit and the sound producing unit,
the group number storage unit is further configured to store a second group number,
the wireless communication unit is further configured to wirelessly receive second control information for controlling the operation of another one of the light emitting unit and the sound producing unit assigned to the second group number,
the control unit is configured to control the operation of the one of the light emitting unit and the sound producing unit based on the control information and the group number stored in the group number storage unit, and control the operation of the other one of the light emitting unit and the sound producing unit based on the second control information and the second group number stored in the group number storage unit,
the information generation device is further configured to generate the second control information for the second group number, and
the control information transmission wireless communication device is further configured to wirelessly transmit the second control information to all of the plurality of entertainment apparatuses.

12. The entertainment system according to claim 7, wherein the wireless communication is communication using infrared rays.

13. The entertainment system according to claim 7, wherein the wireless communication is communication using magnetisms.
